(19) United States
(12) Patent Application Publication
(10) Pub. No.: US 2016/0163896 A1
(43) Pub. Date: Jun. 9, 2016

(54) PROCESS FOR PRODUCING A P-N JUNCTION IN A CZTS-BASED PHOTOVOLTAIC CELL AND CZTS-BASED SUPERSTRATE PHOTOVOLTAIC CELL

(71) Applicant: COMMISSARIAT A L'ENERGIE ATOMIQUE ET AUX ENERGIES ALTERNATIVES, Paris (FR)

(72) Inventors: Louis Grenet, Grenoble (FR); Giovanni Altamura, Grenoble (FR); David Kohen, Villeurbanne (FR); Raphaël Fillon, Grenoble (FR); Simon Perraud, Bandol (FR)

(73) Assignee: COMMISSARIAT A L'ENERGIE ATOMIQUE ET AUX ENERGIES ALTERNATIVES, Paris (FR)

(21) Appl. No.: 14/908,932

(22) PCT Filed: Jul. 22, 2014
(86) PCT No.: PCT/IB2014/063305

§ 371 Date: Jan. 29, 2016

(30) Foreign Application Priority Data
Aug. 1, 2013 (FR) 1357660

(51) Int. Cl. H01L 31/032; H01L 31/0336; H01L 31/072; H01L 31/0224; H01L 31/18; H01L 31/0445

(52) U.S. Cl. CPC H01L 31/0326; H01L 31/18; H01L 31/0445; H01L 31/072; H01L 31/022466; H01L 31/0336

(57) ABSTRACT

The invention relates to a process for producing a p-n junction in a photovoltaic cell made of thin CZTS-based films, comprising: a) a step of depositing a film of precursors containing zinc, tin and copper, the amount of zinc being larger than that required to convert the precursors into a CZTS type photovoltaic material and b) a step of annealing the precursors, under a sulphur- and/or selenium-containing atmosphere, so as to obtain a photovoltaic film made of CZTS and a buffer layer made of ZnS₁₋ₓSeₓ, where x is comprised between 0 and 1.

The invention relates to the field of photovoltaic solar energy and more particularly to photovoltaic cells in thin layers which give the possibility of directly converting the light from the sun into electricity, by using the electronic properties of suitable materials.

Within the scope of the present invention, by thin layer is meant a layer having a thickness of less than 5 μm, or even less than 3 μm.

The manufacturing of photovoltaic cells requires the formation of a p-n junction between a semiconductor of type p or n, in which light is absorbed, and a semiconductor of type n or p.

At the interface between the semiconductor of type p and of type n, an electric field is formed, allowing separation of the charges which is at the basis of photovoltaic conversion.

A solar cell may have a structure of the substrate or superstrate type.

In a structure of the substrate type, the manufacturing of the solar cell begins by forming on a substrate for example in glass or in polyamide, a metal layer, for example in molybdenum forming the lower electrode.

On this electrode, an absorbent layer for example of type p is then made. This absorbent layer may notably be made in CZTS, which corresponds to the general formula Cu₂ZnSn (S₁₋ₓSeₓ)₄ with 0≦x≦1, or in CIGS.

A buffer layer is then deposited on the absorbent layer. This buffer layer is made in a semiconducting material of type n, for example CdS, Zn S₁₋ₓSeₓ with 0≦x≦1 (designated in the following of the description by ZnS) or In₂Se₃.

This deposition is generally carried out with a chemical bath.

The cell is completed by forming a conducting transparent electrode. This electrode is obtained by depositing a layer of a conductive and transparent oxide, such as AZO, ITO or SnO₂:F, notably deposited by cathode sputtering.

Thus it is possible to refer to the article “Cu₂ZnSn (S₁₋ₓSeₓ)₄ based solar cell produced by selenization of vacuum-deposited precursors”, Louis Grenet et al., Solar Energy Materials & Solar Cells 101 (2012) 11-14 which describes a solar cell of the substrate type with an absorbent layer in CZTS and a buffer layer in CdS.

The same stack of layers may also be obtained by depositing the layers in the reverse direction, so as to obtain a structure of the superstrate type. With such a structure, incident light passes through the transparent substrate before attaining the absorbent layer.

Thus, the manufacturing of a solar cell of the superstrate type begins by the deposition of a conductive transparent electrode on a transparent substrate. A buffer layer, of type n or p is then deposited on this conductive transparent electrode, an absorbent layer of type p or n then being formed on the buffer layer. The manufacturing of the solar cell is ended by producing a conductive layer (for example a metal layer) forming a rear electrode.

The manufacturing of solar cells in a superstrate configuration has advantages in terms of costs. Indeed, it gives the possibility of directly using the transparent substrates including a conductive transparent electrode which are provided by the glass industry. Further, this configuration simplifies the step for encapsulating solar cells, required for protecting them from the external environment.

The cells in a superstrate configuration are typically made with an absorbent layer in CdTe.

Moreover, it appears desirable to produce the solar cells with an absorbent layer in CZTS. Indeed, this material contains elements abundantly present in nature and which are non-toxic, unlike CdTe.

Now, conventional processes do not give the possibility of obtaining a solar cell in a superstrate configuration comprising an absorbent layer in CZTS.

Actually, when the buffer layer is made in CdS or In₂Se₃, during the annealing step required for transforming precursors of CZTS into CZTS, the cadmium or the indium diffuses into the absorbent layer. This is due to the fact that annealing is carried out at a high temperature, i.e. at a temperature comprised between 500 and 600° C. Now, diffusion of cadmium or indium occurs as soon as the temperature attains 350° C.

Thus, it is not possible to obtain a photovoltaic cell in a superstrate configuration including a buffer layer in CdS or In₂Se₃, as well as a photovoltaic material layer in CZTS.

When the buffer layer is made in ZnS, no diffusion of the zinc, of the sulfur and/or of the selenium is observed in the photovoltaic material. However, as the ZnS layer is deposited with a chemical bath, it contains many defects related to the inclusion of oxygen or hydrogen atoms for example. These atoms are, on the other hand, capable of diffusing into the CZTS layer, during the annealing step.

The object of the invention is to overcome these drawbacks by proposing a method allowing the production of solar cells based on CZTS and in a superstrate configuration, this method being moreover simplified as compared with the one conventionally used for obtaining a solar cell based on CZTS in a substrate configuration.

The invention first of all relates to a process for producing a pn junction in a photovoltaic cell in thin layers based on CZTS, comprising:

a) a step for depositing a layer of precursors containing zinc, tin and copper, the amount of zinc being greater than the one required for transforming the precursors into a photovoltaic material of the CZTS type and

b) a step for annealing the precursors, in a sulfur and/or selenium atmosphere, so as to obtain a photovoltaic layer in CZTS and a buffer layer in ZnS₁₋ₓSeₓ, with x comprised between 0 and 1.

In an alternative, during step a), selenium and/or sulfur is deposited in an elementary form or as compounds.

In another alternative, during step a) magnesium and/or oxygen are also deposited, the obtained buffer layer being then in Zn₁₋ₓMgₓO_{y}S_{z}Se_{1-y-z} with x and (y+z) comprised between 0 and 1.

Preferably, during step a), it is first of all proceeded with the deposition of a zinc layer and then with the deposition of a layer containing zinc, tin and copper, in the required amounts for forming the CZTS.

In this case, during the deposition of either one or both of these layers, selenium and/or sulfur may also be deposited.

Alternatively, during the deposition of either one or both of these layers, magnesium and/or oxygen is also deposited.

The invention also relates to a method for producing a solar cell based on CZTS and in a superstrate configuration, comprising the following steps:
obtaining a transparent substrate including a conductive and transparent electrode,
applying the method for obtaining a pn junction according to the invention, the buffer layer in ZnS₁₋ₓSeₓ with x comprised between 0 and 1 being obtained between the transparent electrode and the absorbent CZTS layer and
depositing a conductive layer in order to obtain an electrode on the rear face.

The invention also relates to a photovoltaic cell in thin layers and in a superstrate configuration successively comprising:
a transparent substrate with a conductive transparent electrode,
a buffer layer in ZnS₁₋ₓSeₓ with x such that 0≦x≦1,
an absorbent CZTS layer and
an electrode on the rear face.

The invention also relates to a photovoltaic cell in thin layers and in a superstrate configuration successively comprising:
a transparent substrate with a conductive transparent electrode,
a buffer layer in Zn₁₋ₓMgₓO_{y}S_{z}Se_{1-y-z} with x, y and z such that 0≦x≦1 and 0≦y+z<1,
an absorbent CZTS layer and
an electrode on the rear face.

Preferably, the rear face electrode is a layer of molybdenum.

The invention will be better understood and other objects, advantages and features thereof will become more clearly apparent upon reading the description which follows and which is made with reference to the appended drawings, wherein:

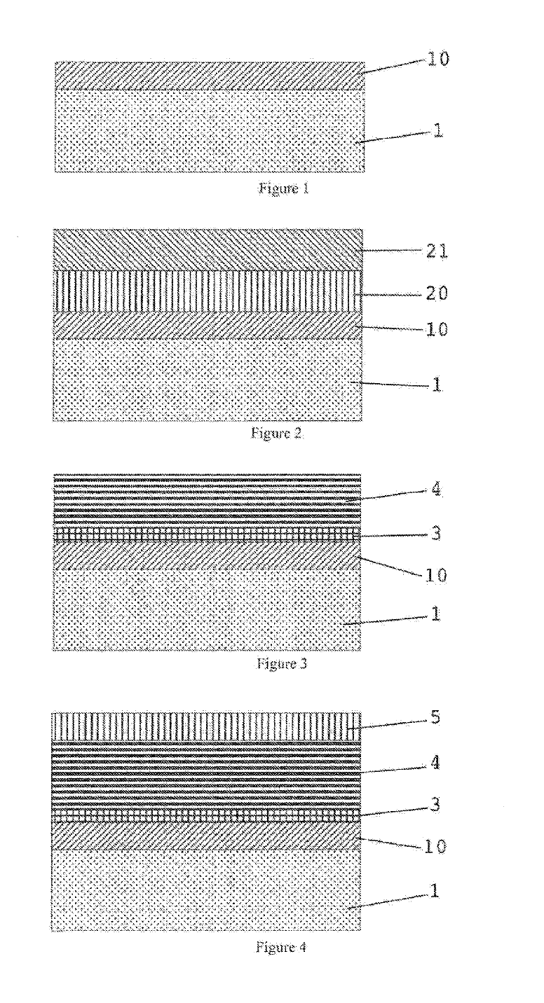

FIG. 1 is a sectional view illustrating a substrate with a transparent and conductive electrode,

FIG. 2 is a sectional view of a stack of layers obtained after the step for depositing precursors of the method according to the invention,

FIG. 3 is a sectional view of the stack illustrated in FIG. 1, after the annealing step, and

FIG. 4 illustrates a solar cell obtained with the method according to the invention.

The elements common to the different figures will be designated with the same references.

With reference to FIG. 1, the method for producing a photovoltaic cell according to the invention first of all consists of obtaining a transparent substrate 1 on which a transparent and conductive electrode 10 was formed. It will be designated as a front face electrode, the incident light being intended to cross the substrate 1.

This substrate may notably consist of glass or of another transparent material in the range 300 nm-1,500 nm. Preferably, substrates are used, provided by the glass industry and on which a transparent electrode is already present.

FIG. 2 illustrates another step, in which on the electrode 10 a zinc layer 20, followed by a layer 21 of precursors containing zinc, tin and copper is deposited in the amounts required for forming CZTS.

It will be recalled here that the ratios of the Cu, Zn and Sn elements are conventionally selected so that: 0.75≦Cu/(Zn+Sn)≦0.95 and 1.05≦Zn/Sn≦1.35 in order to obtain a CZTS layer.

This deposition layer may also be produced by depositing a single layer of precursors containing zinc, tin and copper, the amount of zinc then being greater than the one required for transforming the precursors into a photovoltaic material of the CZTS type.

In this case, the ratios of the elements Cu, Zn and Sn are selected so that 0.6≦Cu/(Zn+Sn)≦0.9 and 1.3≦Zn/Sn≦1.9.

Thus, the amount of zinc will be provided in excess by about 5 to 35% relatively to the amount of tin given by rated stoichiometry of CZTS and the amount of copper will be provided to be less than about 5 to 25% relatively to the amount given by the rated stoichiometry.

In both cases, the precursors may be deposited in vacuo, notably by cathode sputtering or by evaporation, or further via a liquid route, notably by electrodeposition.

Moreover, these deposits may be made at room temperature or at a high temperature which may attain 600° C.

After this deposition step, the stack is subject to an annealing step, in a sulfur and/or selenium atmosphere.

This annealing step is carried out at temperatures comprised between 300 and 700° C. and typically of the order of 500° C.

This step lasts for between 1 and 90 mins. This duration is typically of the order of about 10 mins.

The stack is placed in an inert gas (argon or nitrogen), at a pressure close to atmospheric pressure, typically comprised between 1 mbar and 10 bars.

Moreover, the chalcogen (S and/or Se) may be provided as an elementary gas or as a gas of the H₂S or H₂Se type.

FIG. 3 illustrates a stack which is obtained at the end of the annealing step.

Thus, on the transparent electrode 10, a buffer layer 3 is formed and on this layer 3, an absorbent layer 4.

The layer 3 is formed in a material of general formula ZnS₁₋ₓSeₓ, with x comprised between 0 and 1 and notably such that 0<x≦1. For the sake of simplification, this material is designated by ZnS.

Moreover, the layer 4 is formed in CZTS.

Thus, a single deposition step, followed by a single annealing step, gives the possibility of producing both a buffer layer and an absorbent layer. This has a significant advantage as compared with conventional methods.

It should be noted that, when a layer of precursors containing zinc, tin and copper is deposited on the layer 10, the amount of zinc is in excess, the annealing step leads to pushing back the zinc towards the transparent electrode 10 in order to form the ZnS material.

As an alternative, the precursors may be deposited as compounds with a chalcogen (S and/or Se), for example Cu (S and/or Se) or Zn (S and/or Se). The chalcogen(s) may also be deposited in elementary form. Both of these types of deposition are possible whether the deposition of the precursors is ensured simultaneously or successively, in the form of two layers 20 and 21 as illustrated in FIG. 2.

Moreover, magnesium and/or oxygen may also be deposited with the precursors.

The magnesium and/or oxygen may be deposited by elementary deposition or by reactive deposition in an oxygen atmosphere of certain precursors.

In this case, the buffer layer obtained is in a material represented by the general formula (Mg) Zn(O)S. This formula corresponds to materials of the Zn₁₋ₓMgₓO_{y}S_{z}Se_{1-y-z} type, with x comprised between 0 and 1 as well as (y+z), y and z being notably such that 0≦y+z<1.

The presence of magnesium or oxygen gives the possibility of improving the performances of the final photovoltaic cell.

Indeed, it gives the possibility of reducing the potential barriers between the absorbent layer and the buffer layer. This increases the current and the form factor and therefore the yield in the cells.

This provision of magnesium and/or oxygen may be achieved regardless of whether the precursors are deposited simultaneously or sequentially, as illustrated in FIG. 2.

As an example, the substrate 1 is produced from soda-lime glass including a transparent electrode in SnO₂:F.

The layer 20 has a thickness comprised between 10 and 100 nm when it only includes zinc and it typically has a thickness of 30 nm.

When the layer 20 includes zinc and a chalcogen, it has a thickness comprised between 20 and 200 nm and which is typically equal to 50 nm.

Moreover, the layer 21 for example comprises a layer of ZnS for which the thickness is 340 nm, a copper layer for which the thickness is 110 nm, and a tin layer for which the thickness is 160 nm.

The indicated values correspond to a thickness of the layer 20 of 30 nm (Zn) or 50 nm (ZnS).

With these values, after the annealing steps under the conditions which are for example given hereafter, a buffer layer is obtained in ZnS for which the thickness is of about 50 nm as well as a layer 4 in CZTS for which the thickness is of about 1,000 nm.

Provision may also be made for depositing, on the electrode 10, a ZnS layer for which the thickness is of about 400 nm. This deposition is typically achieved by cathode sputtering.

On this ZnS layer a copper layer for which the thickness is 110 nm and a tin layer for which the thickness is of about 160 nm are then deposited by evaporation with an electron gun.

The obtained stack is then subject to a selenization annealing step. It is carried out at a temperature comprised between 450 and 700° C. and typically equal to 570° C. for a period comprised between 1 and 120 mins and typically equal to 30 mins, under a nitrogen pressure comprised between 10 mbars and 3 atm and notably under atmospheric pressure and under a partial pressure of selenium comprised between 0.01 mbars and 100 mbars and notably 1 mBar. The partial pressure of Se may stem from the evaporation of elementary Se or of H₂Se.

An example of such an annealing step is given in the article mentioned earlier.

In this case, the amount of zinc required for making up the photovoltaic material CZTS is present in the ZnS layer which therefore has a larger thickness than in the previous example (340 nm).

In every case, the deposition and annealing steps give the possibility of producing a buffer layer 3 and an absorbent layer 4, with a p-n junction at the interface between both of these layers.

With the examples indicated earlier, the typical thicknesses are 50 nm for the buffer layer and 1,000 nm for the absorbent layer.

FIG. 4 illustrates the last step of the method, in which a rear face electrode 5 is produced.

This step consists of producing a metal layer.

This layer may be obtained by a simple deposition of conductive metal, notably Au, Cu, Mo or Ti.

This metal deposition may be preceded with chemical cleaning of the surface of the layer 4 and with a doping step in proximity to the surface of the layer 4. In both cases, these preliminary steps have the purpose of improving the electric contact between the layers 4 and 5.

The reference signs inserted after the technical characteristics appearing in the claims have the sole purpose of facilitating understanding of the latter and would not cause any limitation of the scope thereof.

1. A method for producing a p-n junction in a photovoltaic cell in thin layers based on CZTS, comprising:
depositing a layer of precursors containing zinc, tin and copper, the amount of zinc being greater than the one required for transforming the precursors into a photovoltaic material of the CZTS type, and
(b) annealing the precursors, in a sulfur and/or selenium atmosphere, so as to obtain a photovoltaic layer in CZTS and a buffer layer in ZnS₁₋ₓSeₓ, with x comprised between 0 and 1.

2. The method according to claim 1, wherein, during step (a), selenium and/or sulfur are deposited.

3. The method according to claim 1, wherein, during step (a), magnesium and/or oxygen are also deposited, the obtained buffer layer then being in Zn₁₋ₓMgₓO_{y}S_{z}Se_{1-y-z} with x and (y+z) comprised between 0 and 1.

4. The method according to claim 1, wherein, during step (a), it is first of all proceeded with the deposition of a zinc layer and then with the deposition of a layer containing zinc, tin and copper, in the required amounts for forming CZTS.

5. The method according to claim 4, wherein, during the deposition of the zinc layer and/or of the layer containing zinc, tin and copper in the amounts required for forming CZTS, selenium and/or sulfur are also deposited.

6. The method according to claim 4, wherein, during the deposition of the zinc layer and/or of the layer containing zinc, tin and copper in the amounts required for forming CZTS, magnesium and/or oxygen are also deposited.

7. A method for producing a CZTS-based solar cell and in a superstrate configuration, comprising:
obtaining a transparent substrate including a conductive and transparent electrode,
applying the method for obtaining a p-n junction according to claim 1, the buffer layer in ZnS₁₋ₓSeₓ with x comprised between 0 and 1 being obtained between the transparent electrode and the absorbent CZTS layer, and
depositing a conductive layer for obtaining a rear face electrode.

8. A photovoltaic cell in thin layers and in a superstrate configuration successively comprising:
a transparent substrate with a conductive transparent electrode,
a buffer layer in ZnS₁₋ₓSeₓ with x such that 0<x≦1,
an absorbent CZTS layer, and
a rear face electrode.

9. A photovoltaic cell in thin layers and in a superstrate configuration successively comprising:
a transparent substrate with a conductive transparent electrode,
a buffer layer in Zn₁₋ₓMgₓO_{y}S_{z}Se_{1-y-z} with x, (y and z) such that 0≦x≦1 and 0≦y+z<1,
an absorbent CZTS layer, and
a rear face electrode.

10. The photovoltaic cell according to claim 8, wherein the rear face electrode is a molybdenum layer.
